(19) United States
(12) Patent Application Publication
(10) Pub. No.: US 2022/0179304 A1
(43) Pub. Date: Jun. 9, 2022

(54) MASK BLANK SUBSTRATE, SUBSTRATE WITH MULTI-LAYER REFLECTIVE COATING, REFLECTION-TYPE MASK BLANK, REFLECTION-TYPE MASK, TRANSMISSION-TYPE MASK BLANK, TRANSMISSION-TYPE MASK, AND SEMICONDUCTOR DEVICE PRODUCTION METHOD

(71) Applicant: HOYA CORPORATION, Tokyo (JP)

(72) Inventor: Ayumi NAKAMURA, Tokyo (JP)

(73) Assignee: HOYA CORPORATION, Tokyo (JP)

(21) Appl. No.: 17/440,505

(22) PCT Filed: Mar. 19, 2020
(86) PCT No.: PCT/JP2020/012223

§ 371 Date: Sep. 17, 2021

(30) Foreign Application Priority Data
Mar. 29, 2019 (JP) 2019-066684

(51) Int. Cl. G03F 1/60; G03F 1/24; G03F 1/32; H01L 21/027

(52) U.S. Cl. CPC G03F 1/60; H01L 21/0274; G03F 1/32; G03F 1/24

(57) ABSTRACT

When a mask blank substrate is gripped by a transport robot, a pressure is prevented from being locally generated to suppress dust generation from a gripper.

A mask blank substrate comprises: first and second main surfaces; four side faces; first to fourth chamfered faces that are formed between the first main surface and the four side faces; and fifth to eighth chamfered faces that are formed between the second main surface and the four side faces. On a cross section A substantially perpendicular to the first and second main surfaces and to the two side faces, when the seventh chamfered face serves as a reference plane, a parallelism of a contour of the first chamfered face, which is diagonally opposite to the seventh chamfered face, is 0.02 mm or less, and when the first chamfered face serves as a reference plane, a parallelism of a contour of the seventh chamfered face is 0.02 mm or less.

### CROSS-REFERENCE TO RELATED APPLICATIONS

This application is the National Stage of International Application No. PCT/JP2020/012223, filed Mar. 19, 2020, which claims priority to Japanese Patent Application No. 2019-066684, filed Mar. 29, 2019, and the contents of which is incorporated by reference.

### TECHNICAL FIELD

The present disclosure relates to a mask blank substrate, a substrate with a multilayer reflective film, a reflective mask blank, a reflective mask, a transmissive mask blank, a transmissive mask, and a method of manufacturing a semiconductor device.

### BACKGROUND ART

In general, a process of manufacturing a semiconductor device includes forming a fine pattern by using photolithography. To form a fine pattern, a number of transfer masks called photomasks are usually used. In general, the transfer mask is obtained by providing a fine pattern made of a metal thin film or the like on a light-transmissive glass substrate, and photolithography is also used for manufacturing the transfer mask.

For manufacturing a transfer mask using photolithography, a mask blank with a thin film (for example, a light shielding film or the like) is used, the thin film being intended to form a transfer pattern (mask pattern) on a light-transmissive substrate such as a glass substrate. A method of manufacturing a transfer mask using such a mask blank includes a drawing step of drawing a desired pattern on a resist film formed on the mask blank, a developing step of, after the drawing, developing the resist film to form a desired resist pattern, an etching step of etching the thin film using the resist pattern as a mask, and a step of peeling off and removing the remaining resist pattern. In the developing step, a developer is supplied to the resist film formed on the mask blank after a desired pattern is drawn on the resist film. As a result, a portion of the resist film soluble in the developer is dissolved, thereby forming a resist pattern. In the etching step, by using the resist pattern as a mask, a portion of the thin film not covered with the resist pattern and thus exposed is removed by dry etching or wet etching. As a result, a desired mask pattern is formed on the light-transmissive substrate.

Known types of transfer masks include a phase shift-type mask in addition to a conventional binary-type mask that has a light-shielding film pattern made of a chromium-based material on a light-transmissive substrate. The phase shift-type mask includes a light-transmissive substrate and a phase shift film formed on the light-transmissive substrate. The phase shift film, which has a predetermined phase difference, is formed of, for example, a material containing a molybdenum silicide compound, and the like. In addition, a binary-type mask that employs a material containing a silicide compound of a metal such as molybdenum as a light shielding film has been increasingly used. These binary-type and phase shift-type masks are herein collectively referred to as a transmissive mask. In addition, a binary-type mask blank and a phase shift-type mask blank, which are original plates used for transmissive masks, are collectively referred to as a transmissive mask blank.

In recent years, along with higher integration of semiconductor devices, a fine pattern exceeding the transfer limit of a conventional photolithography method employing ultraviolet light has been in demand in the semiconductor industry. As a technology for achieving formation of such a fine pattern, EUV lithography, which is an exposure technology employing extreme ultraviolet (hereinafter referred to as “EUV”) is regarded as promising. Here, EUV light refers to light in a wavelength band of a soft X-ray region or a vacuum ultraviolet region, and more specifically, to light having a wavelength of about 0.2 to 100 nm. As a transfer mask used in the EUV lithography, a reflective mask has been proposed. In such a reflective mask, a multilayer reflective film that reflects exposure light is formed on a substrate, and an absorber film that absorbs the exposure light is formed on the multilayer reflective film. A transfer pattern is formed on the absorber film.

Patent Document 1 describes a low expansion glass substrate serving as a substrate for a reflective mask to be used in a lithography step in a semiconductor production process, in which the flatness of each of two side faces being opposed to each other among the side faces formed along the periphery of the low expansion glass substrate is 25 μm or less and the parallelism between the two side faces is 0.01 mm/inch or less.

### PRIOR ART DOCUMENTS

### Patent Documents

Patent Document 1: JP 5640744 B2

### SUMMARY OF DISCLOSURE

### Technical Problem

As patterns are rapidly becoming finer in lithography employing an ArF excimer laser or extreme ultra-violet (EUV), the defect size of a transmissive mask (also called an optical mask) such as a binary-type mask and a phase shift-type mask or an EUV mask, which is a reflective mask, is also becoming finer year by year. In order to find such a fine defect, the wavelength of an inspection light source used for defect inspections is closer to the wavelength of a light source of exposure light.

A mask blank substrate is a rectangular plate-like object having two main surfaces and four side faces. The two main surfaces are an upper surface and a lower surface of the plate-like object and are formed to be opposed to each other. At least one of the two main surfaces is a main surface on which a transfer pattern is to be formed. The four side faces are formed along the peripheries of the two main surfaces. A chamfered face is formed between each of the two main surfaces and each of the four side faces.

In a semiconductor manufacturing process, various apparatuses (for example, a film forming apparatus and a cleaning apparatus) are used. When a mask blank substrate is conveyed on any of these apparatuses, a transport robot grips the substrate. During the conveyance, the transport robot may grip the chamfered faces of the substrate.

When a transport robot grips the chamfered faces of a conventional mask blank substrate, a pressure may be locally applied to a portion where the gripper of the transport robot is in contact with the chamfered faces to damage the substrate, generating dust from the portion. Such dust generation may cause a defect in a fine pattern formed on the mask blank, and thus it is desirable to suppress the dust generation to the extent possible.

The present disclosure has been made in view of the above circumstances, and an aspect of the present disclosure is to provide a mask blank substrate, a substrate with a multilayer reflective film, a reflective mask blank, a reflective mask, a transmissive mask blank, a transmissive mask, and a method of manufacturing a semiconductor device, in which a pressure is prevented from being locally generated when a transport robot in any of various apparatuses grips the mask blank substrate in a semiconductor manufacturing process so that generation of dust from the gripper is suppressed.

### Solution to Problem

In order to solve the above problems, the present disclosure has the following configurations.

(Configuration 1)

A mask blank substrate comprising:

a first main surface (12a) and a second main surface (12b) that are opposed to each other;

four side faces (16a to 16d) that are formed along peripheries of the first main surface (12a) and the second main surface (12b);

a first chamfered face (18a), a second chamfered face (18b), a third chamfered face (18c), and a fourth chamfered face (18d) that are formed between the first main surface (12a) and the four side faces (16a to 16d); and

a fifth chamfered face (18a′), a sixth chamfered face (18b′), a seventh chamfered face (18c′), and an eighth chamfered face (18d′) that are formed between the second main surface (12b) and the four side faces (16a to 16d), in which

on a cross section (A) that is substantially perpendicular to the first main surface (12a) and the second main surface (12b) and to two (16a and 16c) of the side faces, the two being opposed to each other,

when the seventh chamfered face (18c′) serves as a reference plane (Pc′), a parallelism of a contour (La) of the first chamfered face (18a), which is diagonally opposite to the seventh chamfered face (18c′), is 0.02 mm or less, and

when the first chamfered face (18a) serves as a reference plane, a parallelism of a contour (Lc′) of the seventh chamfered face (18c′) is 0.02 mm or less.

(Configuration 2)

The mask blank substrate according to the configuration 1, in which

on the cross section (A),

when the third chamfered face (18c) serves as a reference plane (Pc), a parallelism of a contour (La′) of the fifth chamfered face (18a′), which is diagonally opposite to the third chamfered face (18c), is 0.02 mm or less, and

when the fifth chamfered face (18a′) serves as a reference plane (Pa′), a parallelism of a contour (Lc) of the third chamfered face (18c) is 0.02 mm or less.

(Configuration 3)

The mask blank substrate according to the configuration 1 or 2, in which

on a cross section (B) that is substantially perpendicular to the first main surface (12a) and the second main surface (12b) and to other two (16b and 16d) of the side faces, the other two being different from the two being opposed to each other, and the other two being opposed to each other,

when the eighth chamfered face (18d′) serves as a reference plane (Pd′), a parallelism of a contour (Lb) of the second chamfered face (18b), which is diagonally opposite to the eighth chamfered face (18d′), is 0.02 mm or less, and

when the second chamfered face (18b) serves as a reference plane (Pb), a parallelism of a contour (Ld′) of the eighth chamfered face (18d′) is 0.02 mm or less.

(Configuration 4)

The mask blank substrate according to any one of the configurations 1 to 3, in which

on the cross section (B),

when the fourth chamfered face (18d) serves as a reference plane (Pd), a parallelism of a contour (Lb′) of the sixth chamfered face (18b′), which is diagonally opposite to the fourth chamfered face (18d), is 0.02 mm or less, and

when the sixth chamfered face (18b′) serves as a reference plane (Pb′), a parallelism of a contour (Ld) of the fourth chamfered face (18d) is 0.02 mm or less.

(Configuration 5)

A substrate with a multilayer reflective film, the substrate comprising: the mask blank substrate according to any one of the configurations 1 to 4; a multilayer reflective film that is formed on one of the first main surface and the second main surface of the mask blank substrate and that reflects EUV light; and a protective film that is formed on the multilayer reflective film.

(Configuration 6)

A reflective mask blank comprising: the substrate with the multilayer reflective film according to the configuration 5; and an absorber film that is to serve as a transfer pattern formed on the protective film of the substrate with the multilayer reflective film.

(Configuration 7)

A reflective mask comprising: the substrate with the multilayer reflective film according to the configuration 5; and an absorber film pattern that is formed on the protective film of the substrate with the multilayer reflective film.

(Configuration 8)

A transmissive mask blank comprising: the mask blank substrate according to any one of the configurations 1 to 4; and a light shielding film that is to serve as a transfer pattern formed on one of the first main surface and the second main surface of the mask blank substrate.

(Configuration 9)

A transmissive mask comprising: the mask blank substrate according to any one of the configurations 1 to 4; and a light shielding film pattern that is formed on one of the first main surface and the second main surface of the mask blank substrate.

(Configuration 10)

A method of manufacturing a semiconductor device, the method comprising performing a lithography process that employs an exposure apparatus using the reflective mask according to the configuration 7 to form a transfer pattern on a transferred object.

(Configuration 11)

A method of manufacturing a semiconductor device, the method comprising performing a lithography process that employs an exposure apparatus using the transmissive mask according to the configuration 9 to form a transfer pattern on a transferred object.

### Advantageous Effects of Disclosure

According to the present disclosure, it is made possible to provide a mask blank substrate, a substrate with a multilayer reflective film, a reflective mask blank, a reflective mask, a transmissive mask blank, a transmissive mask, and a method of manufacturing a semiconductor device, in which a pressure is prevented from being locally generated when a transport robot in any of various apparatuses grips the mask blank substrate in a semiconductor manufacturing process so that generation of dust from the gripper is suppressed.

### BRIEF DESCRIPTION OF DRAWINGS

FIG. 1 is a perspective view of a mask blank substrate.

FIG. 2 is a cross-sectional view of the mask blank substrate 10 taken along line II-II shown in FIG. 1.

FIG. 3 is a cross-sectional view of the mask blank substrate 10 taken along line III-III shown in FIG. 1.

FIG. 4 is a perspective view showing an example of a method of measuring a parallelism.

FIG. 5 is a top view showing an example of the state in which the substrate is gripped by a robot arm of a transport robot.

FIG. 6 is a side view showing an example of the state in which the substrate is gripped by a robot arm of a transport robot.

FIG. 7 is a perspective view showing a cross section A used for measuring a parallelism.

FIG. 8 is an enlarged cross-sectional view of a first chamfered face.

FIG. 9 is a schematic diagram illustrating a substrate with a multilayer reflective film.

FIG. 10 is a schematic diagram illustrating a reflective mask blank.

FIG. 11 is a schematic diagram illustrating a reflective mask.

FIG. 12 is a schematic diagram illustrating a transmissive mask blank.

FIG. 13 is a schematic diagram illustrating a transmissive mask.

FIG. 14 is an explanatory diagram of a contour.

### DESCRIPTION OF EMBODIMENTS

Embodiments of the present disclosure will be described in detail below. Note that each of the following embodiments is one mode for embodying the present disclosure and does not limit the present disclosure within the scope thereof.

[Mask Blank Substrate]

First, a mask blank substrate of the present embodiment will be described.

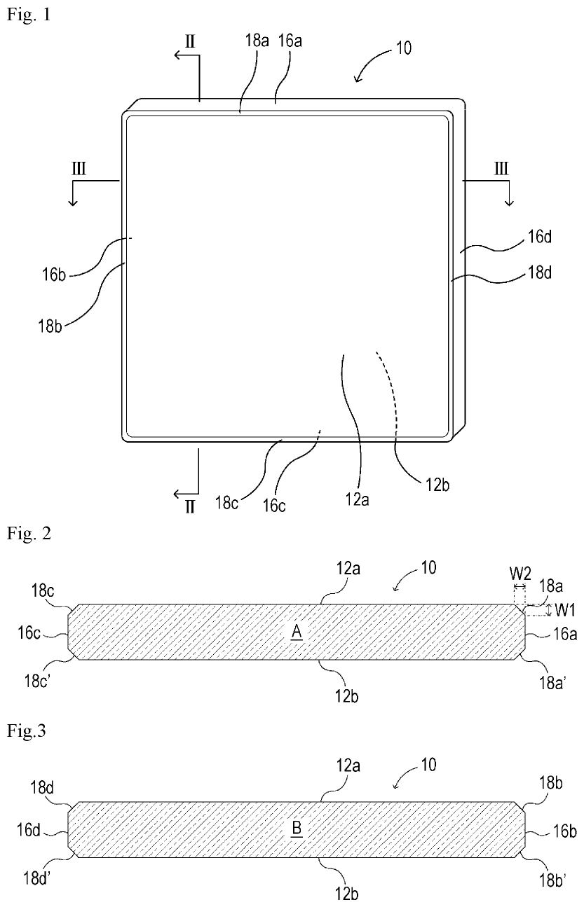

FIG. 1 is a perspective view illustrating a mask blank substrate 10 according to the present embodiment. FIG. 2 is a cross-sectional view of the mask blank substrate 10 taken along line II-II shown in FIG. 1. FIG. 3 is a cross-sectional view of the mask blank substrate 10 taken along line III-III shown in FIG. 1.

The mask blank substrate 10 (which may be hereinafter simply referred to as a substrate 10) is made of a substantially quadrangular plate-like object having two main surfaces 12 (12a and 12b) and four side faces 16 (16a to 16d). The two main surfaces 12a and 12b opposed to each other form an upper surface and a lower surface of the substrate 10. At least one of the two main surfaces 12a and 12b is a surface on which a thin film serving as a transfer pattern is formed.

Note that “upper” as used herein does not necessarily mean an upper side with respect to the vertical direction. In addition, “lower” does not necessarily mean a lower side with respect to the vertical direction. These terms are used merely for convenience to explain the positional relationship between members or parts.

The four side faces 16a to 16d are formed along the peripheries of the substantially quadrangular main surfaces 12a and 12b. First to fourth chamfered faces 18a to 18d are formed between the four side faces 16a to 16d and one main surface 12a. Fifth to eighth chamfered faces 18a′ to 18d′ are formed between the four side faces 16a to 16d and the other main surface 12b.

Each of the side faces 16 (16a to 16d) is a face substantially perpendicular to the two main surfaces 12a and 12b, and may be called a “T face”.

The chamfered faces 18 (18a to 18d and 18a′ to 18d′) are faces formed between the two main surfaces 12a and 12b and the side faces 16a to 16d by being chamfered obliquely. The chamfered faces 18 each may be called a “C face”.

A cross section substantially perpendicular to the first and second main surfaces 12a and 12b and to the two side faces 16a and 16c opposed to each other is herein referred to as a cross section A. A cross section substantially perpendicular to the first and second main surfaces 12a and 12b and to the two side faces 16b and 16d opposed to each other is herein referred to as a cross section B. The cross section A is the cross section shown in FIG. 2. The cross section B is the cross section shown in FIG. 3. The cross section A and the cross section B are orthogonal to each other. The cross section A is a cross section at any position along the longitudinal direction of the two side faces 16a and 16c. The cross section B is a cross section at any position along the longitudinal direction of the two side faces 16b and 16d. Here, “substantially perpendicular” means that the squareness of two faces is 3.5×10⁴ or less.

On the cross section A of the mask blank substrate 10 of the present embodiment, when the seventh chamfered face 18c′ serves as a reference plane Pc′, the parallelism of the contour La of the first chamfered face 18a diagonally opposite to the seventh chamfered face 18c′ is 0.02 mm or less. In addition, when the first chamfered face 18a serves as a reference plane Pa, the parallelism of the contour Lc′ of the seventh chamfered face 18c′ is 0.02 mm or less. More preferably, the parallelism of each of these contours is 0.01 mm or less. Here, the “parallelism” indicates the degree of allowed widening of a linearly-shaped object with respect to the reference plane.

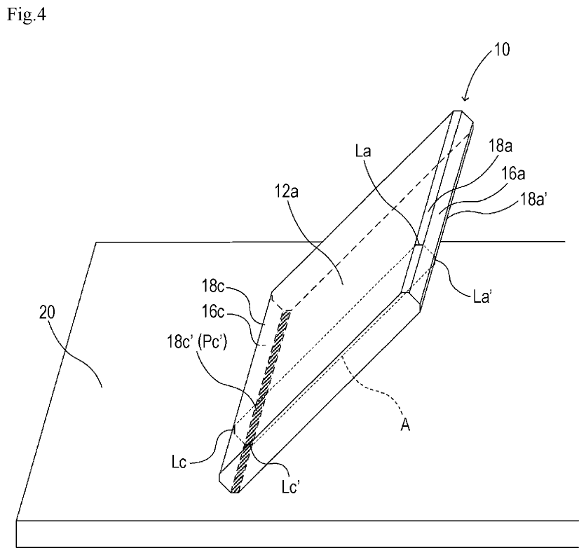

FIG. 4 is a perspective view showing an example of a method of measuring a parallelism.

In order to measure the parallelism, first, as illustrated in FIG. 4, the substrate 10 is placed on a surface plate 20 having an ensured flatness such that the seventh chamfered face 18c′ is in contact with the surface plate 20. The seventh chamfered face 18c′ in contact with the surface plate 20 serves as a reference plane Pc′. Next, the height of the contour La of the first chamfered face 18a diagonally opposite to the seventh chamfered face 18c′ is measured by a combination of a dial gauge and a height gauge. The difference between the minimum and maximum values of the measured height of the contour La is the parallelism. The height of the contour La may be measured by using a three-dimensional coordinate measuring machine.

Description is given above about an example measurement of the parallelism of the first chamfered face 18a with respect to the seventh chamfered face 18c′ serving as the reference plane Pc′, and the same applies vice versa. That is, the substrate 10 is placed on the surface plate 20 having an ensured flatness such that the first chamfered face 18a is in contact with the surface plate 20. The first chamfered face 18a in contact with the surface plate 20 serves as a reference plane Pa. Next, the height of the contour Lc′ of the seventh chamfered face 18c′ diagonally opposite to the first chamfered face 18a is measured by a combination of a dial gauge and a height gauge. The difference between the minimum and maximum values of the measured height of the contour Lc′ is the parallelism. The height of the contour Lc′ may be measured by using a three-dimensional coordinate measuring machine.

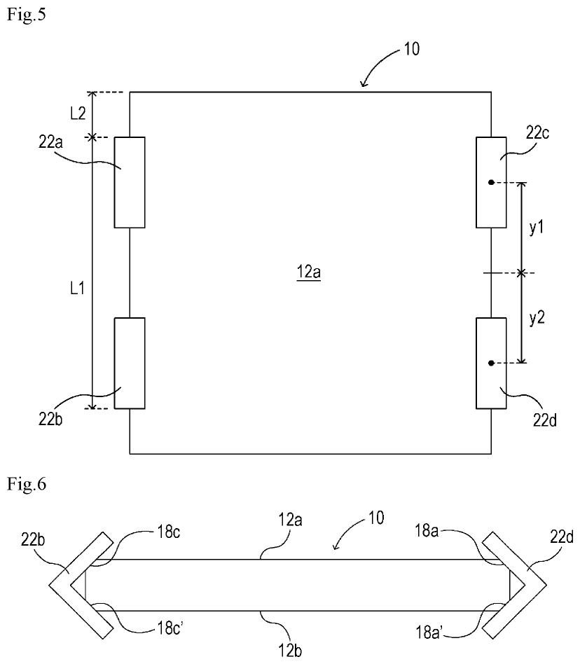

FIG. 5 is atop view showing an example of the state in which the substrate 10 is gripped by a robot arm of a transport robot. FIG. 6 is a side view showing an example of the state in which the substrate 10 is gripped by a robot arm of a transport robot.

As illustrated in FIGS. 5 and 6, in the state where the substrate 10 is held by four robot arms 22a to 22d, the peripheries of the robot arms 22a to 22d are in contact with the four chamfered faces (the first chamfered face 18a, the third chamfered face 18c, the fifth chamfered face 18a′, and the seventh chamfered face 18c′) of the substrate 10.

In this way, when the substrate 10 is conveyed by the transport robot, the substrate 10 held by the robot arms 22a to 22d is moved. During the conveyance, a pressure may be locally applied to points where the robot arms 22a to 22d are in contact with the chamfered faces to cause a damage to the substrate 10, and conventionally the damage may cause dust generation.

The present inventors have found that, on any cross section A of the substrate 10, setting the parallelism of the contour La of the first chamfered face 18a with respect to the seventh chamfered face 18c′ (reference plane Pc′) to 0.02 mm or less and setting the parallelism of the contour Lc′ of the seventh chamfered face 18c′ with respect to the first chamfered face 18a (reference plane Pa) to 0.02 mm or less prevent a pressure from being locally applied to the chamfered faces of the substrate 10 to suppress dust generation from the gripper.

On the cross section A of the mask blank substrate 10 of the present embodiment, when the third chamfered face 18c serves as a reference plane Pc, the parallelism of the contour La′ of the fifth chamfered face 18a′ diagonally opposite to the third chamfered face 18c is preferably 0.02 mm or less. In addition, when the fifth chamfered face 18a′ serves as a reference plane Pa′, the parallelism of the contour Lc of the third chamfered face 18c is preferably 0.02 mm or less. More preferably, the parallelism of each of these contours is 0.01 mm or less. As a result, dust generation from the gripper can be further suppressed. The parallelism is measured in the same manner as in the above-described example measurement of the parallelism of the first chamfered face 18a with respect to the seventh chamfered face 18c′ serving as the reference plane Pc′.

On the cross section B of the mask blank substrate 10 of the present embodiment, when the eighth chamfered face 18d′ serves as a reference plane Pd′, the parallelism of the contour Lb of the second chamfered face 18b diagonally opposite to the eighth chamfered face 18d′ is preferably 0.02 mm or less. In addition, when the second chamfered face 18b serves as a reference plane Pb, the parallelism of the contour Ld′ of the eighth chamfered face 18d′ is preferably 0.02 mm or less. More preferably, the parallelism of each of these contours is 0.01 mm or less. As a result, when the substrate 10 is rotated by 900 and gripped, it is still possible to prevent a pressure from being locally applied to the chamfered faces of the substrate 10 to suppress dust generation from the gripper. The parallelism is measured in the same manner as in the above-described example measurement of the parallelism of the first chamfered face 18a with respect to the seventh chamfered face 18c′ serving as the reference plane Pc′.

On the cross section B of the mask blank substrate 10 of the present embodiment, when the fourth chamfered face 18d serves as a reference plane Pd, the parallelism of the contour Lb′ of the sixth chamfered face 18b′ diagonally opposite to the fourth chamfered face 18d is preferably 0.02 mm or less. In addition, when the sixth chamfered face 18b′ serves as a reference plane Pb′, the parallelism of the contour Ld of the fourth chamfered face 18d is preferably 0.02 mm or less. More preferably, the parallelism of each of these contours is 0.01 mm or less. As a result, when the substrate 10 is rotated by 900 and gripped, it is possible to further suppress dust generation from the gripper. The parallelism is measured in the same manner as in the above-described example measurement of the parallelism of the first chamfered face 18a with respect to the seventh chamfered face 18c′ serving as the reference plane Pc′.

Since the robot arm holds the substrate 10 at, for example, a point included in the range of L1 (for example, 122 mm) excluding L2 (for example, 15 mm from the end of the substrate 10) in FIG. 5, each of the cross section A and the cross section B is preferably included in a range including L1.

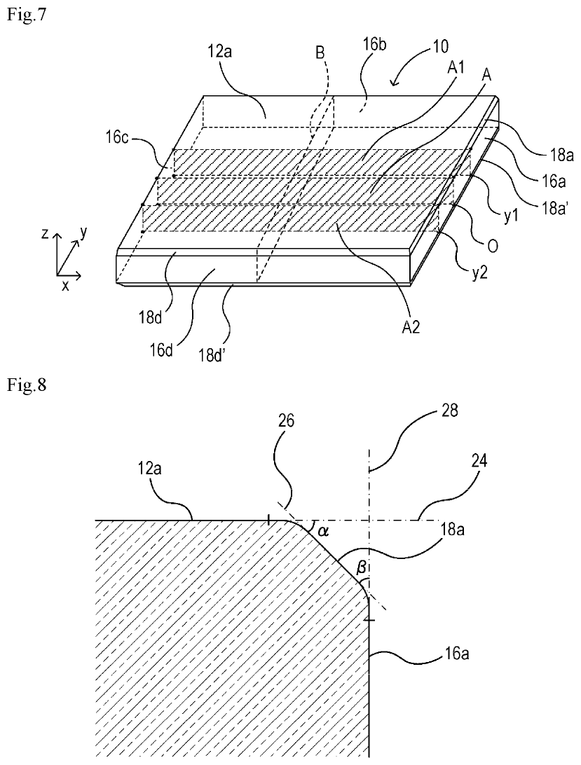

FIG. 7 is a perspective view showing the cross section A used for measuring a parallelism.

As illustrated in FIG. 7, the cross section A for measuring a parallelism is not limited to a single plane but may be any cross section A. For example, assuming that the center position of the first chamfered face 18a with respect to its longitudinal direction (y direction) is denoted as O, both of the cross section A1 located at y1 from the center O and the cross section A2 located at y2 from the center O may be the cross section A used for measuring a parallelism. It is preferable that each of y1 and y2 is used as the center point when the robot arm grips the substrate. As a result, when the four robot arms grip the substrate, dust generation from the gripper can be further suppressed. Preferably, three or more planes are used as a cross section A for measuring a parallelism. Description is given above about the cross section A, and the same applies to the cross section B.

As illustrated in FIG. 2, each of the width W1 and the width W2 of the first chamfered face 18a is preferably in a range of 0.4±0.2 mm, and more preferably in a range of 0.4±0.1 mm. The width W1 is a width of the first chamfered face 18a as seen from the first side face 16a side. The width W2 is a width of the first chamfered face 18a as seen from the first main surface 12a side. Each of the widths W1 and W2 of the first chamfered face 18a is in the above-mentioned range, with the result that it is made possible to more effectively prevent a pressure from being locally applied to a point where the robot arm is in contact with the first chamfered face 18a. As a result, dust generation from the gripper of the robot arm can be more effectively suppressed. Description is given above about the first chamfered face 18a, and the same applies to the second to eighth chamfered faces 18b to 18d and 18a′ to 18d′.

FIG. 8 is an enlarged cross-sectional view of the first chamfered face 18a. As shown in FIG. 8, an angle formed between an imaginary reference plane 24 extending from the first main surface 12a and an imaginary reference plane 26 extending from the first chamfered face 18a is denoted as a. An angle formed between an imaginary reference plane 28 extending from the first side face 16a and an imaginary reference plane 26 extending from the first chamfered face 18a is denoted as β. Then, preferably |α−β|≤0 to 2° is satisfied. The absolute value of the difference between the angle α and the angle β is in the above-mentioned range, with the result that it is made possible to more effectively prevent a pressure from being locally applied to a point where the robot arm is in contact with the first chamfered face 18a. As a result, dust generation from the gripper of the robot arm can be more effectively suppressed. Description is given above about the first chamfered face 18a, and the same applies to the second to eighth chamfered faces 18b to 18d and 18a′ to 18d′.

In addition, in order to enhance the transfer accuracy and/or the positional accuracy of a pattern, it is preferable to provide surface processing on the main surface of the mask blank substrate 10 of the present embodiment on the side where a transfer pattern is formed so that the main surface has a high flatness. In the case of a reflective mask blank substrate for EUV exposure, the flatness in an area of 132 mm×132 mm or of 142 mm×142 mm of the main surface on the side of the substrate 10 where a transfer pattern is formed is preferably 0.1 μm or less, and more preferably 0.05 μm or less. In addition, the main surface that is opposite to the side on which a transfer pattern is formed and that is to be electrostatically chucked when the substrate is set on an exposure apparatus preferably has a flatness of 0.1 μm or less, and particularly preferably 0.05 μm or less, in an area of 142 mm×142 mm. In the case of the mask blank substrate 10 used for a transmissive mask blank for ArF excimer laser exposure, the flatness in an area of 132 mm×132 mm or of 142 mm×142 mm of the main surface on the side of the substrate where a transfer pattern is formed is preferably 0.3 μm or less, and particularly preferably 0.2 μm or less.

The mask blank substrate 10 of the present embodiment may be a transmissive mask blank substrate or a reflective mask blank substrate.

Any material may be used for a transmissive mask blank substrate for ArF excimer laser exposure as long as the material has light transmissivity with respect to an exposure wavelength. In general, synthetic quartz glass is used. Other materials that may be used include aluminosilicate glass, soda-lime glass, borosilicate glass, and alkali-free glass.

A material of the reflective mask blank substrate for EUV exposure preferably has low thermal expansion properties. For example, so-called multi-component glass such as SiO₂—TiO₂-based glass (binary (SiO₂—TiO₂) and ternary (SiO₂—TiO₂—SnO₂ and the like)), for example, SiO₂—Al₂O₃—Li₂O-based crystallized glass, can be used. Instead of the above-mentioned glass, a substrate made of silicon, metal, or the like can also be used. Examples of the metal substrate include an invar alloy (Fe—Ni-based alloy) and the like.

As described above, since a mask blank substrate for EUV exposure is required to have low thermal expansion properties, a multi-component glass material is used for the substrate. However, a multi-component glass material poses a problem that high smoothness is less likely to be obtained as compared with synthetic quartz glass. In order to solve the problem, a thin film (base layer) made of a metal or an alloy, or a material containing at least one of oxygen, nitrogen, and carbon in addition to the metal or the alloy may be formed on the substrate made of a multi-component glass material.

As a material of the thin film, for example, Ta (tantalum), an alloy containing Ta, or a Ta compound containing at least one of oxygen, nitrogen, and carbon in addition thereto is preferably used. As the Ta compound, for example, TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like can be used. Among these Ta compounds, TaN, TaON, TaCON, TaBN, TaBON, TaBCON, TaHfN, TaHfON, TaHfCON, TaSiN, TaSiON, and TaSiCON, which contain nitrogen (N), are more preferably used.

For the mask blank substrate 10 of the present embodiment, no specific limitation is imposed on a processing method intended to satisfy the above-defined parallelism of 0.02 mm or less. Such parallelism can be achieved by grinding and polishing the chamfered faces while keeping the angle of the substrate 10 constant.

[Substrate with Multilayer Reflective Film]

Next, a substrate with a multilayer reflective film of the present embodiment will be described.

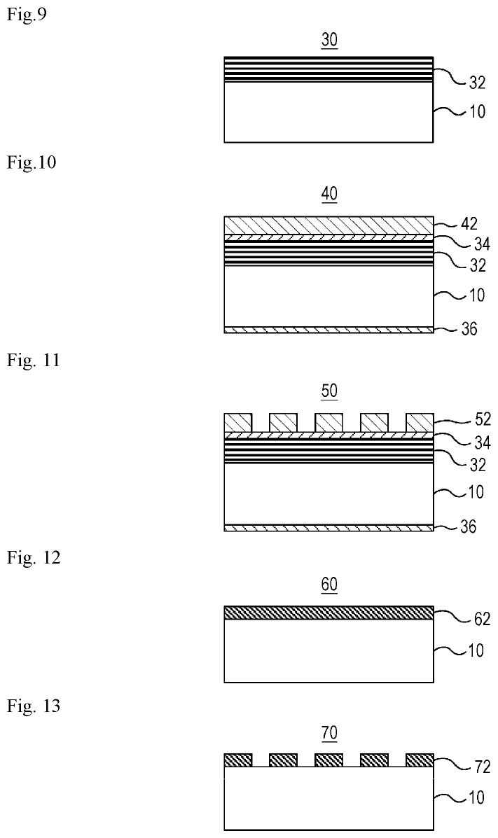

FIG. 9 is a schematic diagram illustrating a substrate with a multilayer reflective film 30 of the present embodiment.

The substrate with a multilayer reflective film 30 of the present embodiment has a configuration in which a multilayer reflective film 32 is formed on the main surface that is the side on which a transfer pattern of the mask blank substrate 10 is formed. The multilayer reflective film 32 imparts a function of reflecting EUV light in a reflective mask for EUV lithography, and includes a multilayer film in which elements having different refractive indexes are periodically layered.

The material of the multilayer reflective film 32 is not particularly limited as long as the material reflects EUV light, and the reflectance of the multilayer reflective film 32 alone is usually 65% or more and the upper limit thereof is usually 73%. In general, such a multilayer reflective film 32 includes a multilayer reflective film in which thin films (high refractive index layers) made of a material having a high refractive index and thin films (low refractive index layers) made of a material having a low refractive index are alternately layered for about 40 to 60 periods.

For example, as the multilayer reflective film 32 for EUV light having a wavelength of 13 to 14 nm, a Mo/Si periodic layered film in which Mo films and Si films are alternately layered for about 40 periods is preferably used. Other examples of the multilayer reflective film used in an EUV light region includes a Ru/Si periodic multilayer film, a Mo/Be periodic multilayer film, a Mo compound/Si compound periodic multilayer film, a Si/Nb periodic multilayer film, a Si/Mo/Ru periodic multilayer film, a Si/Mo/Ru/Mo periodic multilayer film, and a Si/Ru/Mo/Ru periodic multilayer film.

The multilayer reflective film 32 can be formed by a method known in the art. For example, each layer can be formed by a magnetron sputtering method, an ion beam sputtering method, or the like. In the case of the above-mentioned Mo/Si periodic multilayer film, for example, a Si film having a thickness of several nanometers is first formed on the substrate 10 using a Si target by, for example, an ion beam sputtering method. Then, a Mo film having a thickness of several nanometers is formed using a Mo target. This formation is counted as one period and the Si film and the Mo film can be layered for 40 to 60 periods to form the multilayer reflective film 32.

A protective film 34 (see FIG. 10) may be formed on the multilayer reflective film 32 formed as described above, in order to protect the multilayer reflective film 32 from dry etching and wet cleaning in a process of manufacturing the reflective mask for EUV lithography.

Examples of the material of the protective film 34 include a material containing at least one selected from the group consisting of Ru, Ru—(Nb, Zr, Y, B, Ti, La, Mo), Si—(Ru, Rh, Cr, B), Si, Zr, Nb, La, and B. When a material containing ruthenium (Ru), among others, is used, the reflectance characteristics of the multilayer reflective film are improved. Specifically, Ru and Ru—(Nb, Zr, Y, B, Ti, La, Mo) are preferred materials of the protective film 34. Such a protective film is particularly effective in a case where the absorber film includes a Ta-based material and the absorber film is patterned by dry etching with a Cl-based gas.

For the purpose of electrostatic chucking, a conductive back film 36 (see FIG. 10) may be formed on the substrate 10 on the surface opposite to the surface in contact with the multilayer reflective film 32. An electrical characteristic (sheet resistance) required of the conductive back film 36 is usually 100Ω/□ or less. The conductive back film 36 can be formed by a known method. For example, the conductive back film 36 can be formed by a magnetron sputtering method or an ion beam sputtering method using a metal target such as Cr or Ta or an alloy thereof.

The above-described base layer may be formed between the substrate 10 and the multilayer reflective film 32. The base layer may be formed for the purposes of improving smoothness of the main surface of the substrate 10, reducing defects, improving reflectance of the multilayer reflective film 32, reducing stress in the multilayer reflective film 32, and the like.

[Reflective Mask Blank]

Next, a reflective mask blank of the present embodiment will be described.

FIG. 10 is a schematic diagram illustrating a reflective mask blank 40 of the present embodiment.

The reflective mask blank 40 of the present embodiment has a configuration in which an absorber film 42 serving as a transfer pattern is formed on the protective film 34 of the above-described substrate with a multilayer reflective film 30.

The material of the absorber film 42 is not particularly limited as long as the material has a function of absorbing EUV light. For example, Ta (tantalum) alone or a material containing Ta as a main component is preferably used. The material containing Ta as a main component is, for example, an alloy of Ta. Alternatively, examples of the material containing Ta as a main component include a material containing Ta and B, a material containing Ta and N, a material containing Ta and B and further containing at least one of O and N, a material containing Ta and Si, a material containing Ta, Si, and N, a material containing Ta and Ge, and a material containing Ta, Ge, and N.

The reflective mask blank of the present embodiment is not limited to the configuration illustrated in FIG. 10. For example, a resist film serving as a mask for patterning the absorber film 42 may be formed on the absorber film 42. The resist film formed on the absorber film 42 may be of positive type or negative type. In addition, the resist film formed on the absorber film 42 may be intended for electron beam drawing or for laser drawing. Furthermore, a hard mask (etching mask) film may be formed between the absorber film 42 and the resist film.

[Reflective Mask]

Next, a reflective mask 50 of the present embodiment will be described.

FIG. 11 is a schematic diagram illustrating the reflective mask 50 of the present embodiment.

The reflective mask 50 of the present embodiment includes an absorber film pattern 52 obtained by patterning the absorber film 42 of the reflective mask blank 40 described above. In the reflective mask 50 of the present embodiment, exposure light is absorbed in a certain portion of the absorber film pattern 52, while the exposure light is reflected in a portion where the multilayer reflective film 32 (or the protective film 34) is exposed by removing the absorber film 42. Thus, the reflective mask 50 of the present embodiment can be used as, for example, a reflective mask for the lithography that uses EUV light as exposure light.

[Transmissive Mask Blank]

Next, a transmissive mask blank 60 of the present embodiment will be described below.

FIG. 12 is a schematic diagram illustrating the transmissive mask blank 60 of the present embodiment.

The transmissive mask blank 60 of the present embodiment has a configuration in which a light shielding film 62 serving as a transfer pattern is formed on the main surface of the mask blank substrate 10 on the side where the transfer pattern is to be formed.

The transmissive mask blank 60 may be, for example, a binary-type mask blank or a phase shift-type mask blank. The light shielding film 62 may include a light shielding film having a function of shielding exposure light. Alternatively, the light shielding film 62 may include a halftone film that attenuates the exposure light and shifts the phase of the exposure light.

In a binary-type mask blank, a light shielding film that shields exposure light is formed on the mask blank substrate 10. The light shielding film can be patterned to form a desired transfer pattern. Examples of the light shielding film include a Cr film, a Cr alloy film selectively containing oxygen, nitrogen, carbon, and fluorine in addition to Cr, a layered film thereof, a MoSi film, a MoSi alloy film selectively containing oxygen, nitrogen, and carbon in addition to MoSi, and a layered film thereof. An antireflection layer having an antireflection function may be formed on a surface of the light shielding film.

In a phase shift-type mask blank, a phase shift film that changes the phase of exposure light is formed on the mask blank substrate 10. The phase shift film can be patterned to form a desired transfer pattern. Examples of the phase shift film may include a SiO₂ film having a phase shifting function. Examples of the phase shift film may further include halftone films such as a metal silicide oxide film, a metal silicide nitride film, a metal silicide oxynitride film, a metal silicide oxycarbide film, a metal silicide oxynitride carbide film (metals are transition metals such as Mo, Ti, W, and Ta), a CrO film, a CrF film, and a SiON film that have phase shifting and light shielding functions. The above-described light shielding film may be formed on the phase shift film.

The transmissive mask blank of the present embodiment is not limited to the configuration illustrated in FIG. 12. For example, a resist film serving as a mask for patterning the light shielding film 62 may be formed on the light shielding film 62.

The resist film formed on the light shielding film 62 may be of positive type or negative type. In addition, the resist film formed on the light shielding film 62 may be intended for electron beam drawing or for laser drawing. Furthermore, a hard mask (etching mask) film may be formed between the light shielding film 62 and the resist film.

[Transmissive Mask]

Next, a transmissive mask of the present embodiment will be described.

FIG. 13 is a schematic diagram illustrating a transmissive mask 70 of the present embodiment.

The transmissive mask 70 of the present embodiment includes a light shielding film pattern 72 obtained by patterning the light shielding film 62 of the transmissive mask blank 60 described above. The transmissive mask 70 of the present embodiment may be, for example, a binary-type mask or a phase shift-type mask.

In a binary-type mask, exposure light is blocked in a portion where the light shielding film pattern 72 is present. The exposure light passes through a portion where the mask blank substrate 10 is exposed by removing the light shielding film 62. Thus, the transmissive mask 70 can be used as, for example, a transmissive mask for the lithography that uses ArF excimer laser light as exposure light.

In a halftone-type phase shift mask, which is a type of phase shift-type masks, the exposure light passes through a portion where the mask blank substrate 10 is exposed by removing the light shielding film 62. In a portion where the light shielding film pattern 72 is present, the exposure light is attenuated and the phase of the exposure light is shifted. Thus, the transmissive mask 70 can be used as, for example, a phase shift-type mask for the lithography that uses ArF excimer laser light as exposure light.

[Method of Manufacturing Semiconductor Device]

A semiconductor device can be manufactured by a lithography process that employs the reflective mask 50 or the transmissive mask 70 described above and an exposure apparatus. Specifically, the absorber film pattern 52 of the reflective mask 50 or the light shielding film pattern 72 of the transmissive mask 70 is transferred to a resist film formed on a semiconductor substrate. After that, through necessary steps including a development step, a cleaning step, and the like, a semiconductor device in which a pattern (a circuit pattern, for example) is formed on a semiconductor substrate can be manufactured.

### EXAMPLES

As the mask blank substrate 10, a plurality of SiO₂—TiO₂-based glass substrates each having a size of 154.2 to 154.4 mm square and a thickness of 7.4 mm were prepared. Each of the prepared glass substrates was ground to have chamfered faces, and then the chamfered faces were polished. The grinding and the polishing were performed with the glass substrate disposed at a constant angle. Then, the front surface and the back surface of the glass substrate were polished stepwise with cerium oxide abrasive grains or colloidal silica abrasive grains by using a double-side polishing apparatus. After that, the front surface of the glass substrate was treated with low-concentration fluosilicic acid. Next, the front surface and the back surface of the glass substrate were finish-polished with colloidal silica abrasive grains. After that, the glass substrate was washed with an alkaline aqueous solution (NaOH) to obtain a mask blank substrate 10 for EUV exposure.

The obtained mask blank substrates 10 each had a size of 152 mm×152 mm, a thickness of 6.4 mm, and chamfered faces whose widths W1 and W2 were within the range of 0.4±0.2 mm.

Parallelisms of the obtained mask blank substrates 10 were measured on the cross sections A1 and A2 shown in FIG. 7. Specifically, as illustrated in FIG. 4, the substrate 10 was placed on the surface plate 20 having an ensured flatness such that the chamfered face serving as a reference plane was in contact with the surface plate 20. Next, the height of the contour La of the chamfered face diagonally opposite to the reference plane was measured.

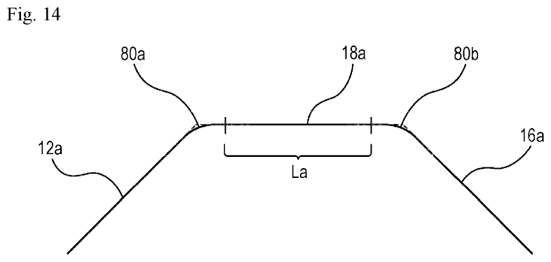

Here, the “contour” refers to a straight line portion that is an intersection line between the chamfered face diagonally opposite to the reference plane and the cross section A1 or A2 excluding curved line portions 80a and 80b at both ends (see FIG. 14). For example, in the case where the chamfered face diagonally opposite to the reference plane is the “first chamfered face 18a”, the curved line portion 80a is a ridge line portion between the first main surface 12a and the first chamfered face 18a. The curved line portion 80b is a ridge line portion between the first chamfered face 18a and the first side face 16a. Since these ridge line portions have a curved cross section when viewed microscopically, the height of a straight line portion (the contour La) from the reference plane excluding these curved line portions was measured.

Specifically, the heights of four points on the contour La were measured in a measurement range of 0.3 mm (see FIG. 14) by combining a dial gauge and a height gauge, and the difference between the maximum value and the minimum value was calculated as the parallelism. Table 1 shows results of Samples 1 to 3, which were the selected samples satisfying the tolerance of parallelism. The center position of the first chamfered face 18a with respect to its longitudinal direction (y direction) was denoted as O, and cross sections located at distances of y1=y2=21 mm from the center O were selected as the cross sections A1 and A2.

TABLE 1

| | | Sample 1 | | Sample 2 | | Sample 3 | |
|---|---|---|---|---|---|---|---|
| | | Parallelism | Parallelism | Parallelism | Parallelism | Parallelism | Parallelism |
| | | on cross | on cross | on cross | on cross | on cross | on cross |
| Reference | | section A1 | section A2 | section A1 | section A2 | section A1 | section A2 |
| plane | Contour | (mm) | (mm) | (mm) | (mm) | (mm) | (mm) |
| Pc′ | La | 0.007 | 0.006 | 0.014 | 0.013 | 0.018 | 0.017 |
| Pa | Lc′ | 0.006 | 0.008 | 0.013 | 0.013 | 0.019 | 0.018 |
| Pc | La′ | 0.008 | 0.007 | 0.015 | 0.014 | 0.017 | 0.017 |
| Pa′ | Lc | 0.009 | 0.008 | 0.014 | 0.015 | 0.016 | 0.015 |

A defect inspection (first) was conducted on a surface of each of the selected three mask blank substrates 10. For the defect inspection, a high-sensitivity defect inspection apparatus with an inspection light source wavelength of 193 nm (“Teron 600 Series” manufactured by KLA-Tencor Corporation) was used. With the defect inspection apparatus, the defect inspection was conducted on a 132 mm×132 mm area of the main surface of the glass substrate. As an inspection sensitivity condition, the inspection sensitivity condition under which a defect having a sphere equivalent volume diameter (SEVD) of 20 nm can be detected was used. The sphere equivalent volume diameter (SEVD) can be calculated by the formula SEVD=2(3S/4πh)^{1/3}, where S is the area of a defect in plan view and h is the height of the defect (the same applies to the comparative example below). The area (S) of a defect and the height (h) of the defect can be measured by an atomic force microscope (AFM). As a result, it was found that the number of defects on the surface was zero in Sample 1, two in Sample 2, and three in Sample 3 and almost no dust was generated.

For each of Samples 1 to 3 described above, parallelisms were measured on the cross section B1 and the cross section B2 orthogonal to the cross section A1 or the cross section A2. The center position of the second chamfered face 18b with respect to its longitudinal direction (x direction) was denoted as O, and cross sections located at distances of x1=x2=21 mm from the center O were selected as the cross sections B1 and B2. The measurement was performed in the same manner as for the cross sections A1 and A2. Table 2 shows the measurement results.

TABLE 2

| | | Sample 1 | | Sample 2 | | Sample 3 | |
|---|---|---|---|---|---|---|---|
| | | Parallelism | Parallelism | Parallelism | Parallelism | Parallelism | Parallelism |
| | | on cross | on cross | on cross | on cross | on cross | on cross |
| Reference | | section B1 | section B2 | section B1 | section B2 | section B1 | section B2 |
| plane | Contour | (mm) | (mm) | (mm) | (mm) | (mm) | (mm) |
| Pd′ | Lb | 0.006 | 0.007 | 0.014 | 0.015 | 0.019 | 0.018 |
| Pb | Ld′ | 0.008 | 0.009 | 0.013 | 0.014 | 0.017 | 0.016 |
| Pd | Lb′ | 0.007 | 0.008 | 0.014 | 0.014 | 0.016 | 0.017 |
| Pb′ | Ld | 0.007 | 0.006 | 0.015 | 0.014 | 0.018 | 0.017 |

The mask blank substrate 10 was rotated by 90° from the state in which the mask blank substrate 10 was subjected to the first defect inspection. The rotated mask blank substrate 10 was gripped, and a defect inspection similar to the first inspection was conducted. As a result, it was found that the number of defects on the surface was zero in Sample 1, two in Sample 2, and four in Sample 3 and dust generation was almost the same as in the first inspection.

### Comparative Example

In the comparative example, the chamfered faces were ground and polished without controlling angles of the glass substrate. Except that, the same process as in the above example was carried out to obtain a mask blank substrate 10. Parallelisms of the obtained mask blank substrates 10 were measured on the cross sections A1 and A2 shown in FIG. 7. Table 3 shows the results.

TABLE 3

| | | Sample 4 | | Sample 5 | |
|---|---|---|---|---|---|
| | | Parallelism | Parallelism | Parallelism | Parallelism |
| | | on cross | on cross | on cross | on cross |
| Reference | | section A1 | section A2 | section A1 | section A2 |
| plane | Contour | (mm) | (mm) | (mm) | (mm) |
| Pc’ | La | 0.06 | 0.05 | 0.10 | 0.10 |
| Pa | Lc’ | 0.04 | 0.05 | 0.09 | 0.08 |
| Pc | La’ | 0.05 | 0.06 | 0.11 | 0.10 |
| Pa’ | Lc | 0.07 | 0.09 | 0.10 | 0.09 |

The defect inspection was conducted on a surface of each of the obtained two mask blank substrates 10. As a result, it was found that the number of defects on the surface was 13 in Sample 4 and 16 in Sample 5 and much more dust generation was observed than in the example above.

### REFERENCE SIGNS LIST

10 Mask blank substrate
12a First main surface
12b Second main surface
16a First side face
16b Second side face
16c Third side face
16d Fourth side face
18a First chamfered face
18b Second chamfered face
18c Third chamfered face
18d Fourth chamfered face
18a′ Fifth chamfered face
18b′ Sixth chamfered face
18c′ Seventh chamfered face
18d′ Eighth chamfered face
20 Surface plate
22a to 22d Robot arm
30 Substrate with multilayer reflective film
40 Reflective mask blank
50 Reflective mask
60 Transmissive mask blank
70 Transmissive mask

1. A mask blank substrate comprising:
a first main surface and a second main surface that are opposed to each other;
four side faces that are formed along peripheries of the first main surface and the second main surface;
a first chamfered face, a second chamfered face, a third chamfered face, and a fourth chamfered face that are formed between the first main surface and the four side faces; and
a fifth chamfered face, a sixth chamfered face, a seventh chamfered face, and an eighth chamfered face that are formed between the second main surface and the four side faces,
wherein, in a cross section (A) that is substantially perpendicular to the first main surface, to the second main surface, and to two of the four side faces, the two being opposed to each other, the first chamfered face is diagonally opposite to the seventh chamfered face, and
when the seventh chamfered face serves as a reference plane, a parallelism of a contour of the first chamfered face, which is diagonally opposite to the seventh chamfered face, is 0.02 mm or less, and
when the first chamfered face serves as a reference plane, a parallelism of a contour of the seventh chamfered face is 0.02 mm or less.

2. The mask blank substrate according to claim 1, wherein, in the cross section (A), the third chamfered face is diagonally opposite to the fifth chamfered face, and
when the third chamfered face serves as a reference plane, a parallelism of a contour of the fifth chamfered face is 0.02 mm or less, and
when the fifth chamfered face serves as a reference plane, a parallelism of a contour of the third chamfered face is 0.02 mm or less.

3. The mask blank substrate according to claim 1, wherein, in a cross section (B) that is substantially perpendicular to the first main surface, to the second main surface, and to the other two of the four side faces, the other two being opposed to each other, the second chamfered face is diagonally opposite to the eighth chamfered face, and
when the eighth chamfered face serves as a reference plane, a parallelism of a contour of the second chamfered face is 0.02 mm or less, and
when the second chamfered face serves as a reference plane, a parallelism of a contour of the eighth chamfered face is 0.02 mm or less.

4. The mask blank substrate according to claim 1, wherein, in the cross section (B), the sixth chamfered face is diagonally opposite to the fourth chamfered face, and
when the fourth chamfered face serves as a reference plane, a parallelism of a contour of the sixth chamfered face is 0.02 mm or less, and
when the sixth chamfered face serves as a reference plane, a parallelism of a contour of the fourth chamfered face is 0.02 mm or less.

5. A substrate with a multilayer reflective film, the substrate comprising:
the mask blank substrate according to claim 1;
a multilayer reflective film that is formed on one of the first main surface and the second main surface of the mask blank substrate and that reflects EUV light; and
a protective film that is formed on the multilayer reflective film.

6. A reflective mask blank comprising:
a mask blank substrate having a first main surface and a second main surface that are opposed to each other;
a multilayer reflective film that is formed on one of the first main surface and the second main surface of the mask blank substrate and that reflects EUV light
a protective film that is formed on the multilayer reflective film; and
an absorber film to serve as a transfer pattern on the protective film,
wherein the mask blank substrate also has:
four side faces that are formed along peripheries of the first main surface and the second main surface;
a first chamfered face, a second chamfered face, a third chamfered face, and a fourth chamfered face that are formed between the first main surface and the four side faces; and
a fifth chamfered face, a sixth chamfered face, a seventh chamfered face, and an eighth chamfered face that are formed between the second main surface and the four side faces, and
wherein, in a cross section (A) that is substantially perpendicular to the first main surface, to the second main surface, and to two of the four side faces, the two being opposed to each other, the first chamfered face is diagonally opposite to the seventh chamfered face, and
when the seventh chamfered face serves as a reference plane, a parallelism of a contour of the first chamfered face is 0.02 mm or less, and
when the first chamfered face serves as a reference plane, a parallelism of a contour of the seventh chamfered face is 0.02 mm or less.

7. A reflective mask comprising:
the substrate with the multilayer reflective film according to claim 5; and
an absorber film pattern that is formed on the protective film of the substrate with the multilayer reflective film.

8. A transmissive mask blank comprising:
a mask blank substrate having a first main surface and a second main surface that are opposed to each other; and
a light shielding film to serve as a transfer pattern on one of the first main surface and the second main surface of the mask blank substrate,
wherein the mask blank substrate also has: the first main surface and the second main surface that are opposed to each other;
four side faces that are formed along peripheries of the first main surface and the second main surface;
a first chamfered face, a second chamfered face, a third chamfered face, and a fourth chamfered face that are formed between the first main surface and the four side faces; and
a fifth chamfered face, a sixth chamfered face, a seventh chamfered face, and an eighth chamfered face that are formed between the second main surface and the four side faces, and
wherein, in a cross section (A) that is substantially perpendicular to the first main surface, to the second main surface and to two of the four side faces, the two being opposed to each other, the first chamfered face is diagonally opposite to the seventh chamfered face, and
when the seventh chamfered face serves as a reference plane, a parallelism of a contour of the first chamfered face is 0.02 mm or less, and
when the first chamfered face serves as a reference plane, a parallelism of a contour of the seventh chamfered face is 0.02 mm or less.

9. A transmissive mask comprising:
the mask blank substrate according to claim 1; and
a light shielding film pattern that is formed on one of the first main surface and the second main surface of the mask blank substrate.

10. A method of manufacturing a semiconductor device, the method comprising performing a lithography process that employs an exposure apparatus using the reflective mask according to claim 7 to form a transfer pattern on a transferred object.

11. A method of manufacturing a semiconductor device, the method comprising performing a lithography process that employs an exposure apparatus using the transmissive mask according to claim 9 to form a transfer pattern on a transferred object.

12. The reflective mask blank according to claim 6, wherein, in the cross section (A), the third chamfered face is diagonally opposite to the fifth chamfered face, and
when the third chamfered face serves as a reference plane, a parallelism of a contour of the fifth chamfered face is 0.02 mm or less, and
when the fifth chamfered face serves as a reference plane, a parallelism of a contour of the third chamfered face is 0.02 mm or less.

13. The reflective mask blank according to claim 6, wherein, in a cross section (B) that is substantially perpendicular to the first main surface, to the second main surface, and to the other two of the four side faces, the other two being opposed to each other, the second chamfered face is diagonally opposite to the eighth chamfered face, and
when the eighth chamfered face serves as a reference plane, a parallelism of a contour of the second chamfered face is 0.02 mm or less, and
when the second chamfered face serves as a reference plane, a parallelism of a contour of the eighth chamfered face is 0.02 mm or less.

14. The reflective mask blank according to claim 6, wherein, in the cross section (B), the sixth chamfered face is diagonally opposite to the fourth chamfered face, and
when the fourth chamfered face serves as a reference plane, a parallelism of a contour of the sixth chamfered face is 0.02 mm or less, and
when the sixth chamfered face serves as a reference plane, a parallelism of a contour of the fourth chamfered face is 0.02 mm or less.

15. The transmissive mask blank according to claim 8, wherein, in the cross section (A), the third chamfered face is diagonally opposite to the fifth chamfered face, and
when the third chamfered face serves as a reference plane, a parallelism of a contour of the fifth chamfered face is 0.02 mm or less, and
when the fifth chamfered face serves as a reference plane, a parallelism of a contour of the third chamfered face is 0.02 mm or less.

16. The transmissive mask blank according to claim 8, wherein, in a cross section (B) that is substantially perpendicular to the first main surface, to the second main surface, and to the other two of the four side faces, the other two being opposed to each other, the second chamfered face is diagonally opposite to the eighth chamfered face, and
when the eighth chamfered face serves as a reference plane, a parallelism of a contour of the second chamfered face is 0.02 mm or less, and
when the second chamfered face serves as a reference plane, a parallelism of a contour of the eighth chamfered face is 0.02 mm or less.

17. The transmissive mask blank according to claim 8, wherein, in the cross section (B), the sixth chamfered face is diagonally opposite to the fourth chamfered face, and
when the fourth chamfered face serves as a reference plane, a parallelism of a contour of the sixth chamfered face is 0.02 mm or less, and
when the sixth chamfered face serves as a reference plane, a parallelism of a contour of the fourth chamfered face is 0.02 mm or less.
